(19) United States
(12) Patent Application Publication
(10) Pub. No.: US 2019/0088908 A1
(43) Pub. Date: Mar. 21, 2019

(54) FLEXIBLE SUBSTRATE STRUCTURE AND MANUFACTURING METHOD THEREOF

(71) Applicant: Immortal Industrial Co., Ltd, Hsinchu City (TW)

(72) Inventors: Chin-Chih Lin, Kaohsiung City (TW); Yu-Hung Chen, Taoyuan City (TW); Meng-Hung Hsin, New Taipei City (TW)

(21) Appl. No.: 15/888,076

(22) Filed: Feb. 4, 2018

Related U.S. Application Data
(60) Provisional application No. 62/560,685, filed on Sep. 20, 2017.

(30) Foreign Application Priority Data
Nov. 14, 2017 (TW) 106139314

(51) Int. Cl. H01L 51/56; H01L 27/12; H01L 51/00

(52) U.S. Cl. CPC H01L 51/56; H01L 27/1218; H01L 27/3276; H01L 27/124; H01L 51/0097

(57) ABSTRACT

A flexible substrate structure includes a flexible substrate, a first patterned metal layer and a second patterned metal layer. The flexible substrate has a first surface and a second surface which is opposite the first surface. The first patterned metal layer is disposed on the first surface of the flexible substrate. The second patterned metal layer is disposed on the second surface of the flexible substrate. The flexible substrate has at least one through hole. A manufacturing method of the flexible substrate structure includes: providing a flexible substrate having a first surface and a second surface which is opposite the first surface; forming a first patterned metal layer on the first surface of the flexible substrate, and forming a second patterned metal layer on the second surface of the flexible substrate; and performing a through hole process for forming at least one through hole in the flexible substrate.

### CROSS REFERENCE TO RELATED APPLICATIONS

This patent application claims the benefit of U.S. Provisional Application No. 62/560,685, filed on Sep. 20, 2017, the entire contents of which are incorporated herein by reference.

### BACKGROUND OF THE INVENTION

### 1. Field of the Invention

The present invention relates to a flexible substrate structure and a manufacturing method thereof, and more particularly to a flexible substrate structure and a manufacturing method thereof configured to be a mask or a base with a double-sided patterned metal layer.

### 2. Description of the Prior Art

When an electronic product (such as an OLED display) is manufactured, a mask such as a metal mask will be used in a manufacturing process of various devices of the electronic product, so that these devices may be disposed at predetermined positions. The metal of the mask has a low stress tolerance. Therefore, when the metal mask receives stress, residual stress exists in the metal mask, or holes of the metal mask increase, adverse conditions such as wrinkles, bending or warping will be generated on the metal mask, which decreases the yield rate of the electronic product; for example, a manufacturing process for a display which utilizes a metal mask may result in a serious color mixture of the display. A conventionally solution for decreasing the influence of stress on the metal mask is to increase space between the holes of the metal mask for increasing its structural stability. Although this solves the abovementioned problem, the resolution of the display will be decreased.

### SUMMARY OF THE INVENTION

One objective of the present invention is to provide a flexible substrate structure and a manufacturing method thereof with a structure having a substrate and at least two metal layers, such that the flexible substrate structure is configured to be a base on which an electronic device is disposed or a mask.

An embodiment of the present invention provides a flexible substrate structure including a flexible substrate, a first patterned metal layer and a second patterned metal layer. The flexible substrate has a first surface and a second surface, wherein the second surface is opposite the first surface. The first patterned metal layer is disposed on the first surface of the flexible substrate. The second patterned metal layer is disposed on the second surface of the flexible substrate. The flexible substrate has at least one through hole.

Another embodiment of the present invention provides a manufacturing method of a flexible substrate structure including the following steps: providing a flexible substrate having a first surface and a second surface which is opposite the first surface; forming a first patterned metal layer on the first surface of the flexible substrate, and forming a second patterned metal layer on the second surface of the flexible substrate; and performing a through hole process for forming at least one through hole in the flexible substrate.

Because the flexible substrate structure of the present invention is formed of the flexible substrate and two patterned metal layers having at least one metal film, the structural stability of the flexible substrate structure configured to be the mask may be increased, thereby reducing adverse conditions such as wrinkles, bending or warping and increasing the yield rate of the electronic product. Furthermore, owing to the advance in structural stability, the distance between the through holes and the number of through holes TH does not need to be decreased therefore; compared to the conventional metal mask, the structures manufactured by the flexible substrate structure of the present invention may have a higher density, which enhances the quality of the electronic product manufactured by the flexible substrate structure. The flexible substrate structure of the present invention may also be configured to be a base on which the electronic device is disposed, in which electronic devices at two sides may be used to manufacture the electronic product. In addition, two patterned metal layers of the flexible substrate structure of the present invention may be formed simultaneously by an electroplating process; thus, the process time and manufacturing cost may be reduced, which enhances the convenience of the manufacturing process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing a top view of a flexible substrate structure of a first embodiment of the present invention.

FIG. 2 is a schematic diagram showing a top view of a portion of the flexible substrate structure of the first embodiment of the present invention.

FIG. 3 is a schematic diagram showing a cross-section of the flexible substrate structure of the first embodiment of the present invention.

FIG. 4A to FIG. 4D are schematic diagrams showing pixels of a display manufactured by a flexible substrate structure of an embodiment of the present invention.

FIG. 5 to FIG. 8 are schematic diagrams showing a cross-section of a manufacturing method of the flexible substrate structure of the first embodiment of the present invention.

FIG. 9 is a schematic diagram showing a flow chart of the manufacturing method of the flexible substrate structure of the present invention.

FIG. 10 to FIG. 11 are schematic diagrams showing a cross-section of a manufacturing method of a flexible substrate structure of a modification of the first embodiment of the present invention.

FIG. 12 is a schematic diagram showing a cross-section of a flexible substrate structure of a second embodiment of the present invention.

FIG. 13 is a schematic diagram showing a cross-section of a flexible substrate structure of a third embodiment of the present invention.

FIG. 14 is a schematic diagram showing a top view of a flexible substrate structure of a fourth embodiment of the present invention.

FIG. 15 is a schematic diagram showing a top view of the flexible substrate structure with an electronic device of the fourth embodiment of the present invention.

### DETAILED DESCRIPTION

To provide a better understanding of the present invention to those skilled in the technology, preferred embodiments will be detailed as follows. The preferred embodiments of the present invention are illustrated in the accompanying drawings with numbered elements to elaborate on the contents and effects to be achieved. It should be noted that the drawings are simplified schematics, and therefore show only the components and combinations associated with the present invention, so as to provide a clearer description of the basic architecture or method of implementation. The components would be complex in reality. In addition, for ease of explanation, the components shown in the drawings may not represent their actual number, shape, and dimensions; details can be adjusted according to design requirements.

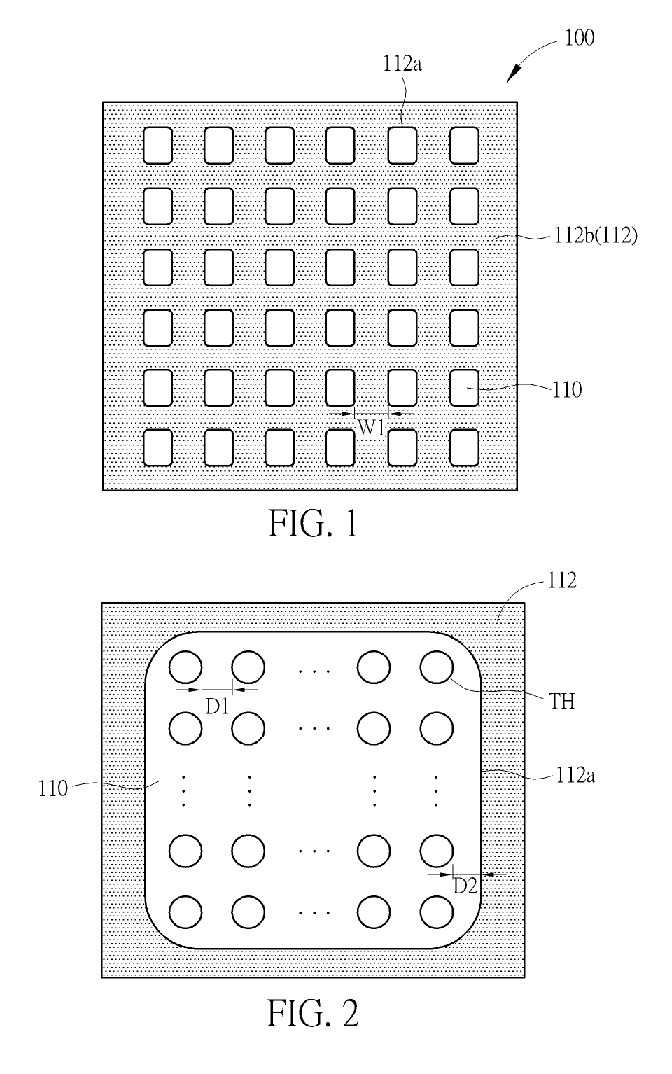

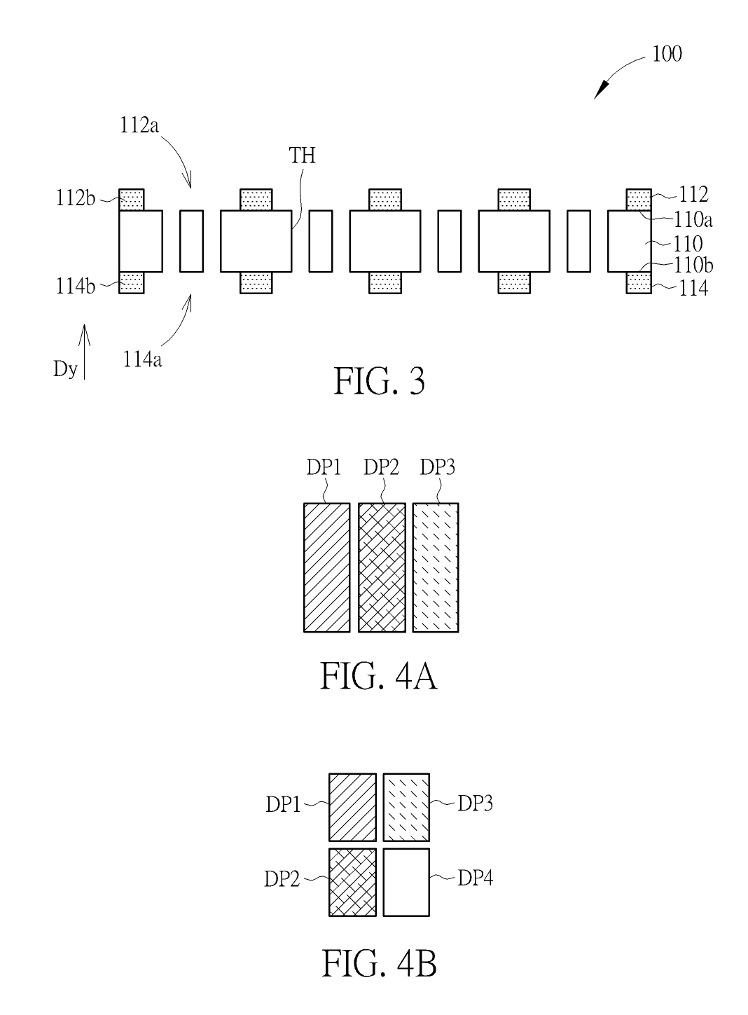

Referring to FIG. 1 to FIG. 3, FIG. 1 is a schematic diagram showing a top view of a flexible substrate structure of a first embodiment of the present invention, FIG. 2 is a schematic diagram showing a top view of a portion of the flexible substrate structure of the first embodiment of the present invention, and FIG. 3 is a schematic diagram showing a cross-section of the flexible substrate structure of the first embodiment of the present invention. As shown in FIG. 1 to FIG. 3, the flexible substrate structure 100 of this embodiment includes the flexible substrate 110, the first patterned metal layer 112 and the second patterned metal layer 114. The flexible substrate 110 is configured to hold components of the flexible substrate structure 100 or electronic devices disposed on the flexible substrate structure 100. The flexible substrate 110 has a first surface 110a and a second surface 110b, wherein the second surface 110b is opposite the first surface 110a. Note that FIG. 1 and FIG. 2 only show the first surface 110a and structures disposed on the first surface 110a. In this embodiment, the flexible substrate 110 may include polyimide (PI) or polyethylene terephthalate (PET) for example, but is not limited thereto.

The first patterned metal layer 112 is disposed on the first surface 110a of the flexible substrate 110, and the second patterned metal layer 114 is disposed on the second surface 110b of the flexible substrate 110. The first patterned metal layer 112 and the second patterned metal layer 114 are disposed on opposite sides of the flexible substrate 110 respectively. Note that the first patterned metal layer 112 and the second patterned metal layer 114 are different films although backgrounds of the first patterned metal layer 112 and the second patterned metal layer 114 shown in figures are the same. The first patterned metal layer 112 may have at least one first opening 112a, and the second patterned metal layer 114 may have at least one second opening 114a. In this embodiment, the first patterned metal layer 112 has a plurality of the first openings 112a, the second patterned metal layer 114 has a plurality of the second openings 114a, and the first openings 112a and the second openings 114a are arranged in an array; i.e. the first patterned metal layer 112 and the second patterned metal layer 114 form grid patterns as shown in FIG. 1, but this is not limited thereto. In another embodiment, the openings in two rows in one patterned metal layer may be misaligned. The first openings 112a and the second openings 114a of this embodiment is quadrangular with round corners, but this is not limited thereto. The pattern and arrangement of the first openings 112a and the second openings 114a may be designed depending on requirements. The patterns of the first patterned metal layer 112 and the second patterned metal layer 114 of this embodiment may be repeatable patterns arranged in an array or arranged in misalignment, and each of the repeatable patterns may be formed of one opening or a plurality of openings which are different sizes, but are not limited thereto. In another embodiment, the patterns of the first patterned metal layer 112 and the second patterned metal layer 114 may be non-repeatable patterns or may have the repeatable patterns at specific positions. Moreover, because the first patterned metal layer 112 and the second patterned metal layer 114 of this embodiment are grid patterns, the first patterned metal layer 112 may be considered to include a plurality of first strip structures 112b, the second patterned metal layer 114 may be considered to include a plurality of second strip structures 114b, the first strip structures 112b are staggered with respect to each other to form the grid pattern of the first patterned metal layer 112, and the second strip structures 114b are staggered with respect to each other to form the grid pattern of the second patterned metal layer 114. In addition, in this embodiment, the first patterned metal layer 112 may completely overlap the second patterned metal layer 114 along a direction Dy perpendicular to the first surface 110a. In other words, the pattern of the first patterned metal layer 112 is the same as the pattern of the second patterned metal layer 114, and the first opening 112a and the second opening 112b overlap correspondingly, but this is not limited thereto. In another embodiment, the first patterned metal layer 112 may not completely overlap the second patterned metal layer 114 along the direction Dy perpendicular to the first surface 110a, such that the pattern of the first patterned metal layer 112 is not the same as the pattern of the second patterned metal layer 114. For example, the first opening 112a and the second opening 112b overlap partially; in another example, the first opening 112a and the second opening 112b are misaligned. Furthermore, the first patterned metal layer 112 and the second patterned metal layer 114 of this embodiment may include non-magnetic metal material (such as palladium (Pd)), magnetic metal material (such as iron (Fe), cobalt (Co) or nickel (Ni)) or alloys of the above metal material (such as stainless steel), but is not limited thereto. That is to say, the first patterned metal layer 112 and the second patterned metal layer 114 include at least one metal material. The material of the first patterned metal layer 112 may be the same as or different from the second patterned metal layer 114. The first patterned metal layer 112 and the second patterned metal layer 114 may be a single-layer structure or a multi-layer structure; that is, the first patterned metal layer 112 and the second patterned metal layer 114 have at least one layer.

As shown in FIG. 2 and FIG. 3, the flexible substrate 110 has at least one through hole TH, wherein an edge of the through hole TH of this embodiment does not overlap the first patterned metal layer 112 and the second patterned metal layer 114 along the direction Dy perpendicular to the first surface 110a, but this is not limited thereto. In this embodiment, the flexible substrate 110 may have a plurality of through holes TH, and the through holes TH may be situated in the first openings 112a and the second openings 114a. Furthermore, the through holes TH are arranged in an array; for example, in this embodiment, all of the through holes TH of the flexible substrate 110 are arranged in an array, each of the first openings 112a may have the through holes TH, and in each of the first openings 112a, the through holes TH are arranged in an array in the corresponding first openings 112a, but this is not limited thereto. In another example, in each of the first openings 112a, the through holes TH are arranged in an array in the corresponding first openings 112a, and a distance between two through holes TH respectively situated in two adjacent first openings 112a and closest to each other is greater than a distance between two through holes TH situated in one first opening 112a, but the disposition of the through holes TH is not limited thereto. In still another embodiment, the through holes TH in two adjacent rows may be misaligned. In addition, a shape of the through hole TH may be a circle, an ellipse, a quadrangle, a triangle or other suitable shape, and the shape may be designed depending on requirements. In FIG. 2, the shape of the through hole TH is circular.

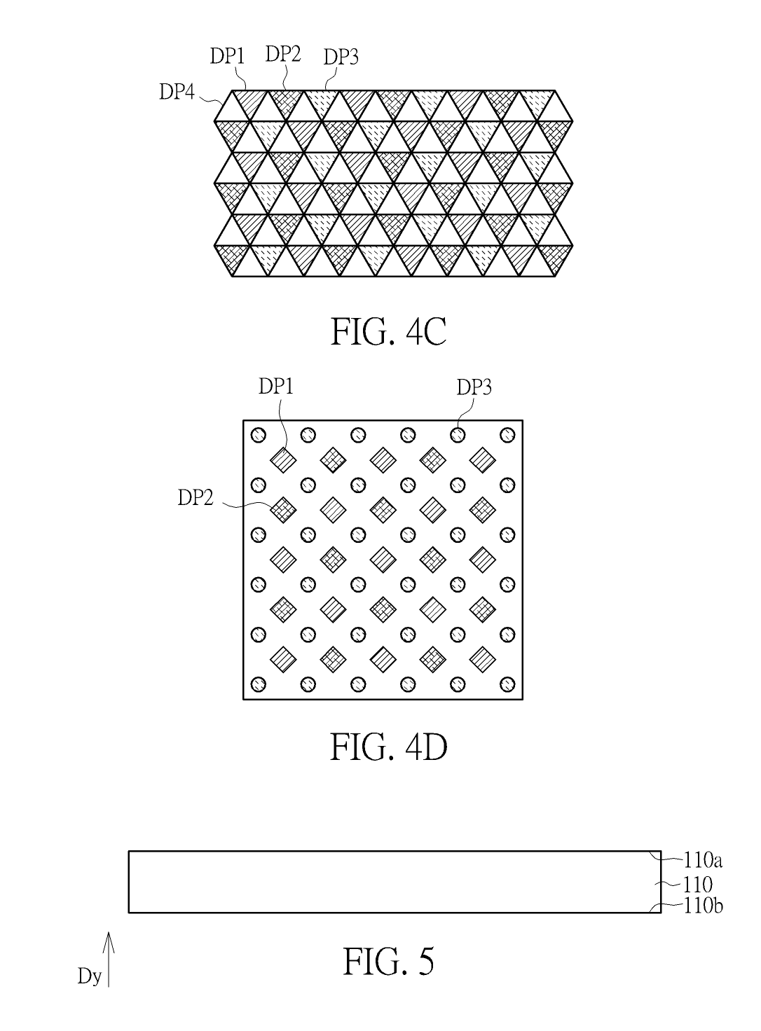

In this embodiment, the flexible substrate structure 100 is configured to be a mask for manufacturing a portion structure of the electronic product. In the manufacturing process of the electronic product, the flexible substrate structure 100 of this embodiment may be set between a raw material supply end of an apparatus and a substrate of the electronic product, such that the raw material provided from the raw material supply end may be disposed on the substrate of the electronic product through the through hole TH of the flexible substrate structure 100, to thereby manufacture a structural portion of the electronic product. For an illustration of the manufacturing process of a display, refer to FIG. 4A to FIG. 4D, which are schematic diagrams showing pixels of a display manufactured by a flexible substrate structure of an embodiment of the present invention, wherein the flexible substrate structure 100 of this embodiment is configured to be a mask for manufacturing display devices (such as OLEDs or color filters) of the display, each of sub-pixels may include at least one of the display devices, and the sub-pixels may form a plurality of pixels. As shown in FIG. 4A, the shape of the through hole TH of the flexible substrate structure 100 is rectangular, and the display devices DP1, DP2 and DP3 arranged side by side may be three different colors, such as red, green and blue, respectively. As shown in FIG. 4B, the shape of the through holes TH of the flexible substrate structure 100 is rectangular also, and the display devices DP1, DP2, DP3 and DP4 arranged in a 2×2 array may be four different colors, such as red, green, blue and white, respectively. In this case, note that four sub-pixels (such as four display devices DP1, DP2, DP3 and DP4) may be arranged to form one of the pixels, but the arrangement and the shape of the sub-pixels may be designed depending on a requirement. As shown in FIG. 4C, the shape of the through hole TH of the flexible substrate structure 100 is triangular, and the display devices DP1, DP2, DP3 and DP4 arranged in delta type may be four colors respectively. As shown in FIG. 4D, the shape of the through hole TH of the flexible substrate structure 100 is quadrangular or elliptical, and the display devices DP1, DP2 and DP3 arranged in a form such as a Pentile type may be three colors respectively. FIG. 4A to FIG. 4D and the aforementioned description are examples, the pixels of the display manufactured by the flexible substrate structure 100 of the present invention are not limited thereto, and other devices of the electronic product and other types or disposition of the pixels may be manufactured by the flexible substrate structure 100. Moreover, in the manufacturing process of the different color display devices, the different display devices may be manufactured by different flexible substrate structures 100, and the numbers, shapes or arrangements of the through holes TH of the different flexible substrate structures 100 are designed depending on a requirement. For example, if the different color display devices have the same number, shape and arrangement (for example, the display devices shown in FIG. 4A and FIG. 4B), the different flexible substrate structures 100 may have the same structure; if the different color display devices have different numbers, shapes or arrangements (for example, the display devices shown in FIG. 4C and FIG. 4D), the display devices may be manufactured by different flexible substrate structures 100 which have different shapes or arrangements of the through holes TH, but this is not limited thereto. Furthermore, because the display devices are manufactured by the through holes TH of the flexible substrate structure 100, the distance between the through holes TH is equal to a distance between sub-pixels of the display.

The first patterned metal layer 112 and the second patterned metal layer 114 of this embodiment may include the magnetic metal material, and the metal material of the first patterned metal layer 112 and the metal material of the second patterned metal layer 114 may have a single component or multiple components; thus, when the flexible substrate structure 100 of this embodiment is set between the raw material supply end of the apparatus and the substrate of the electronic product, the flexible substrate structure 100 may be fixed between the raw material supply end and the substrate of the electronic product by a magnetic force, so as to achieve a better usage quality of the mask. Furthermore, in the manufacturing process of the electronic product, the flexible substrate structure 100 and the electronic product may be shifted or fixed by controlling the magnetic force. In order to achieve a better magnetic adsorption and a better disposition of metal, a width of the first strip structures 112b of the first patterned metal layer 112 and a width of the second strip structures 114b of the second patterned metal layer 114 of this embodiment may range from 0.5 μm to 1000 μm, such as a width W1 shown in FIG. 1, but this is not limited thereto.

In this embodiment, because the flexible substrate structure 100 is formed of two patterned metal layers and the flexible substrate 110, the structural stability of the flexible substrate structure 100 configured to be the mask may be increased. Compared to a conventional metal mask having one patterned metal layer only, adverse conditions such as wrinkles, bending or warping may be reduced in this embodiment of the present invention, which increases the yield rate of the electronic product produced by this mask. In this embodiment, a thickness of the first patterned metal layer 112 and a thickness of the second patterned metal layer 114 may range from about 0.1 μm to about 100 μm, the thickness of the first patterned metal layer 112 may be equal to or different from the thickness of the second patterned metal layer 114, and a thickness of the flexible substrate 110 may range from about 1 μm to about 50 μm, but this is not limited thereto. Moreover, owing to the advance in structural stability, the distance between the through holes TH and the number of through holes TH do not need to be decreased. Therefore, compared to the conventional metal mask, the structures manufactured by the flexible substrate structure 100 of this embodiment of the present invention may have a higher density (such as a pixels density of the display), which enhances the quality of the electronic product manufactured by the flexible substrate structure 100; for example, the resolution of the display may be enhanced. Furthermore, so that the structures manufactured by the flexible substrate structure 100 do not affect each other and have an increased density, in this embodiment, a distance D1 between two adjacent through holes within the plurality of through holes may range from about 0.5 μm to about 500 μm, and a distance between the edge of the through hole TH and an edge of the first opening 112a or a distance between the edge of the through hole TH and the second opening 114a may range from about 0.5 μm to about 500 μm (such as a distance D2). In this design, the pixels density of the display may range from about 10 ppi to about 1700 ppi. In the conventional metal mask, the distance between through holes manufactured by an etching process is at least greater than 50 μm, so the pixels density of the display manufactured by the conventional metal mask is lower than 500 ppi.

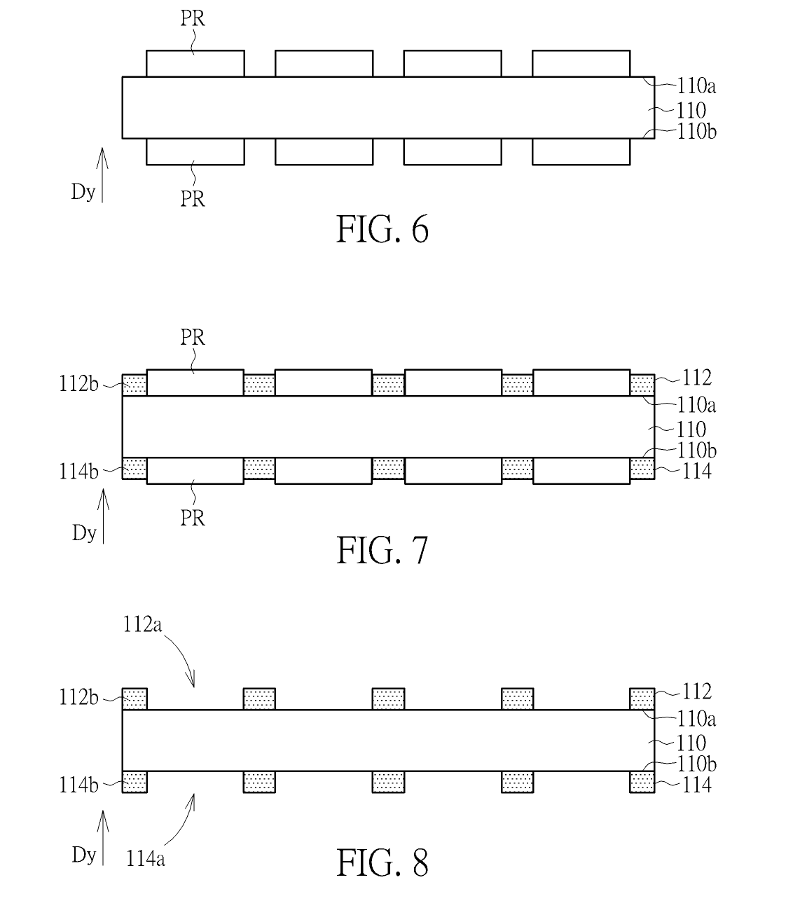

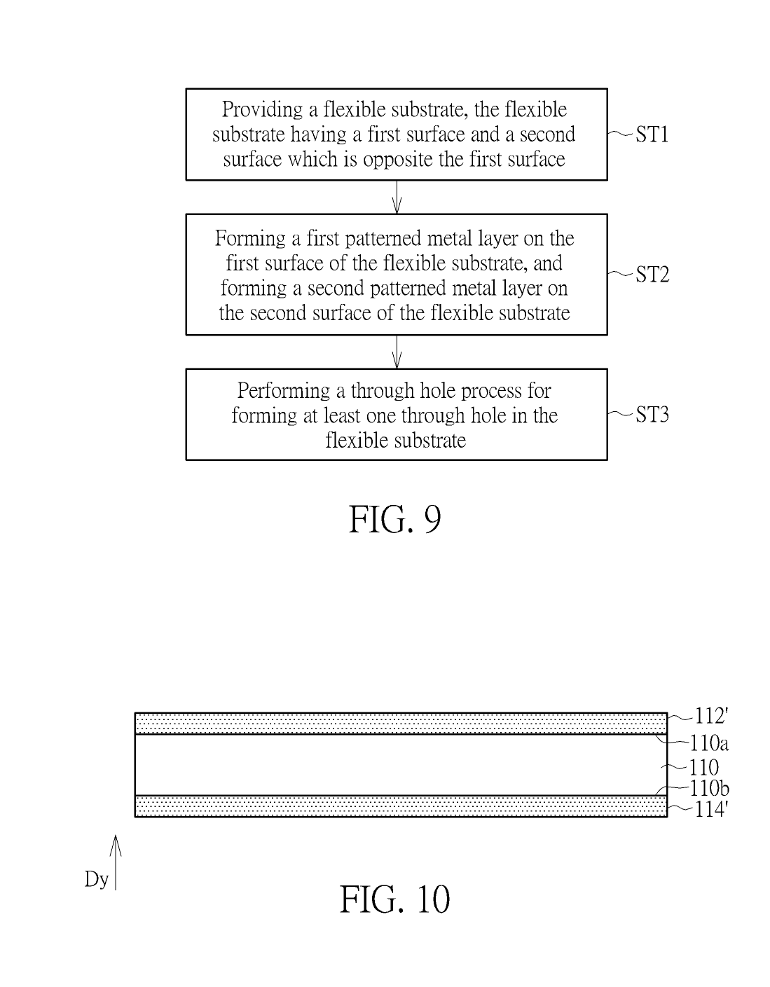

Refer to FIG. 3 and FIG. 5 to FIG. 9. FIG. 5 to FIG. 8 are schematic diagrams showing a cross-section of a manufacturing method of the flexible substrate structure of the first embodiment of the present invention, and FIG. 9 is a schematic diagram showing a flow chart of the manufacturing method of the flexible substrate structure of the present invention. As shown in FIG. 5, in the manufacturing method of the flexible substrate structure 100 of this embodiment, the flexible substrate 110 is provided. Then, as shown in FIG. 6 to FIG. 8, the first patterned metal layer 112 is formed on the first surface 110a of the flexible substrate 110, and the second patterned metal layer 114 is formed on the second surface 110b of the flexible substrate 110. In detail, in this embodiment, before the first patterned metal layer 112 and the second patterned metal layer 114 are formed, a plurality of patterned photoresist layers PR may be respectively formed on the first surface 110a and the second surface 110b of the flexible substrate 110, as shown in FIG. 6. In the forming process of the patterned photoresist layers PR, photoresist layers may be formed on the first surface 110a and the second surface 110b, and then patterns of the photoresist layers may be defined by a photolithography process, so as to form the patterned photoresist layers PR, wherein the patterns of the patterned photoresist layers PR respectively correspond to regions predetermined to form the first openings 112a and the second opening 112b. Hereafter, the patterned photoresist layers PR serve as layers defining the patterns of the patterned metal layers. The first patterned metal layer 112 and the second patterned metal layer 114 are respectively formed on regions without the patterned photoresist layers PR at the first surface 110a and the second surface 110b of the flexible substrate 110, as shown in FIG. 7. A method of forming the first patterned metal layer 112 and the second patterned metal layer 114 includes a chemical deposition process (such as an electroplating process) or a physical attaching process, wherein the electroplating process may form the first patterned metal layer 112 and the second patterned metal layer 114 simultaneously, so as to reduce the process time, decrease manufacturing cost and enhance the convenience of the manufacturing process. The patterned photoresist layers PR are removed after forming the first patterned metal layer 112 and the second patterned metal layer 114, which completes the manufacture of the first patterned metal layer 112 and the second patterned metal layer 114, as shown in FIG. 8. The manufacturing method of the first patterned metal layer 112 and the second patterned metal layer 114 is not limited thereto, however. The first patterned metal layer 112 and the second patterned metal layer 114 may be formed by other methods; for example, two metal layers are formed on the first surface 110a and the second surface 110b of the flexible substrate 110, then, the patterned photoresist layers are formed on the metal layers, the metal layers are etched to form the first patterned metal layer 112 and the second patterned metal layer 114, and next, the patterned photoresist layers are removed. Finally, as shown in FIG. 3, a through hole process is performed for forming at least one through hole TH in the flexible substrate 110, which completes the manufacture of the flexible substrate structure 100. Note that the edge of the through hole TH of this embodiment does not overlap the patterned metal layers, and therefore, in the through hole process, the through hole TH does not pass through the patterned metal layers. In other words, the through hole process is performed at the flexible substrate 110 exposed by the first opening 112a and the second opening 114a. Moreover, after the through hole process, the flexible substrate structure 100 may be cleaned by a chemical or physical method; for example, the flexible substrate structure 100 is soaked in a liquid or a specific environment, removing dirt left by the manufacturing process.

As shown in FIG. 9, the manufacturing method of the flexible substrate structure 100 of this embodiment includes the following steps.

Step ST1: Providing a flexible substrate, the flexible substrate having a first surface and a second surface which is opposite the first surface.

Step ST2: Forming a first patterned metal layer on the first surface of the flexible substrate, and forming a second patterned metal layer on the second surface of the flexible substrate.

Step ST3: Performing a through hole process for forming at least one through hole in the flexible substrate.

The flexible substrate structure and the manufacturing method thereof of the present invention are not limited to the above embodiments. Further embodiments or modifications of the present invention are described below. For ease of comparison, the same components will be labeled with the same symbol in the following. The following descriptions only detail the differences between each of the embodiments, and repeated parts will not be redundantly described.

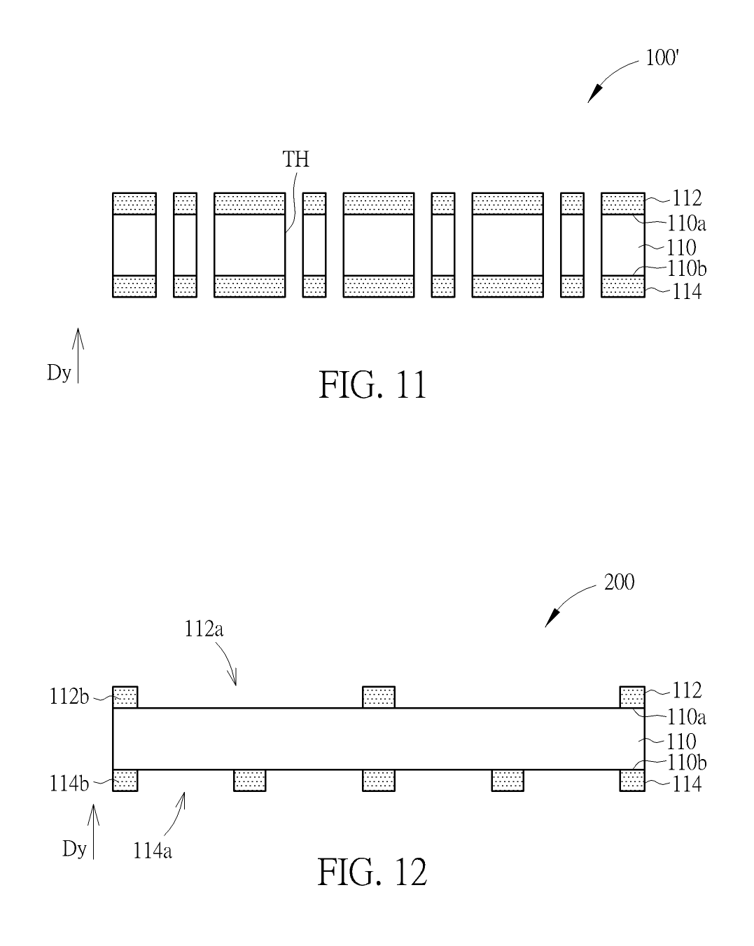

FIG. 10 to FIG. 11 are schematic diagrams showing a cross-section of a manufacturing method of a flexible substrate structure of a modification of the first embodiment of the present invention, wherein FIG. 11 shows a cross-section of the flexible substrate structure of the modification of the first embodiment of the present invention. As shown in FIG. 10, in the manufacturing method of the flexible substrate structure 100′ of this modification, the flexible substrate 110 is provided. Then, a first metal layer 112′ is formed on the first surface 110a of the flexible substrate 110, and a second metal layer 114′ is formed on the second surface 110b of the flexible substrate 110. The forming method of the first metal layer 112′ and the second metal layer 114′ includes the electroplating process or the physical attaching process, but is not limited thereto. Next, as shown in FIG. 11, the through hole process is performed for forming the at least one through hole TH in the flexible substrate 110, the first metal layer 112′ and the second metal layer 114′, so that the first metal layer 112′ and the second metal layer 114′ are formed as the first patterned metal layer 112 and the second patterned metal layer 114, thereby completing the manufacture of the flexible substrate structure 100′. In the manufacturing process of this modification, it should be noted that the through hole TH may pass through the first metal layer 112′ and the second metal layer 114′ directly, so the edge of the through hole TH overlaps the first patterned metal layer 112 and the second patterned metal layer 114 along the direction Dy perpendicular to the first surface 110a. Therefore, compared to the flexible substrate structure 100 of the first embodiment, the first patterned metal layer 112 and the second patterned metal layer 114 do not have the opening (such as the first opening 112a or the second opening 114a of the first embodiment shown in FIG. 1), and the edge of the through hole TH may overlap the first patterned metal layer 112 and the second patterned metal layer 114 along the direction Dy perpendicular to the first surface 110a. Furthermore, the flexible substrate 110, the first patterned metal layer 112 and the second patterned metal layer 114 have the same area and completely overlap each other along the direction Dy perpendicular to the first surface 110a. The thicknesses and materials of each of the films of the flexible substrate structure 100′ and the distance between the through holes TH may be known by referring to the first embodiment; the description will therefore not be repeated.

In another modification, the first patterned metal layer 112 the same as the first embodiment (as shown in FIG. 3) may be disposed on the first surface 110a of the flexible substrate 110 of the flexible substrate structure, and the second patterned metal layer 114 which is the same as the above modification (as shown in FIG. 11, wherein the second patterned metal layer does not have the second opening 114a) may be disposed on the second surface 110b of the flexible substrate 110. Thus, the edge of the through hole TH may overlap the first patterned metal layer 112 and not overlap the second patterned metal layer 114 along the direction Dy perpendicular to the first surface 110a. The thicknesses, materials and manufacturing processes of each of the films of the flexible substrate structure and the distance between the through holes TH may be known by referring to the first embodiment and the above modifications, and the description will therefore not be repeated.

FIG. 12 is a schematic diagram showing a cross-section of a flexible substrate structure of a second embodiment of the present invention, wherein FIG. 12 does not show the through holes TH in order to simplify the schematic diagram. As shown in FIG. 12, compared to the first embodiment, the first patterned metal layer 112 of the flexible substrate structure 200 of this embodiment does not completely overlap the second patterned metal layer 114 along the direction Dy perpendicular to the first surface 110a. In other words, the pattern of the first patterned metal layer 112 is not the same as the pattern of the second patterned metal layer 114. In this embodiment, the first patterned metal layer 112 partially overlaps the second patterned metal layer 114, but is not limited thereto. In another embodiment, the first strip structures 112b of the first patterned metal layer 112 and the second strip structures 114b of the second patterned metal layer 114 may be misaligned with respect to each other along the direction Dy perpendicular to the first surface 110a. In addition, the number of the first openings 112a of this embodiment is less than the number of the second openings 114a, and an area of the first opening 112a is greater than an area of the second opening 114a, but the embodiment is not limited thereto. The disposition of the patterned metal layers, the number of openings, the area of the opening and the location of the opening may be designed depending on requirements; for example, in another embodiment, the pattern of the first patterned metal layer 112 and the pattern of the second patterned metal layer 114 shown in FIG. 12 are exchanged; in still another embodiment, the first patterned metal layer 112 may have a plurality of first openings 112a, and the second patterned metal layer 114 may have only one second opening 114a.

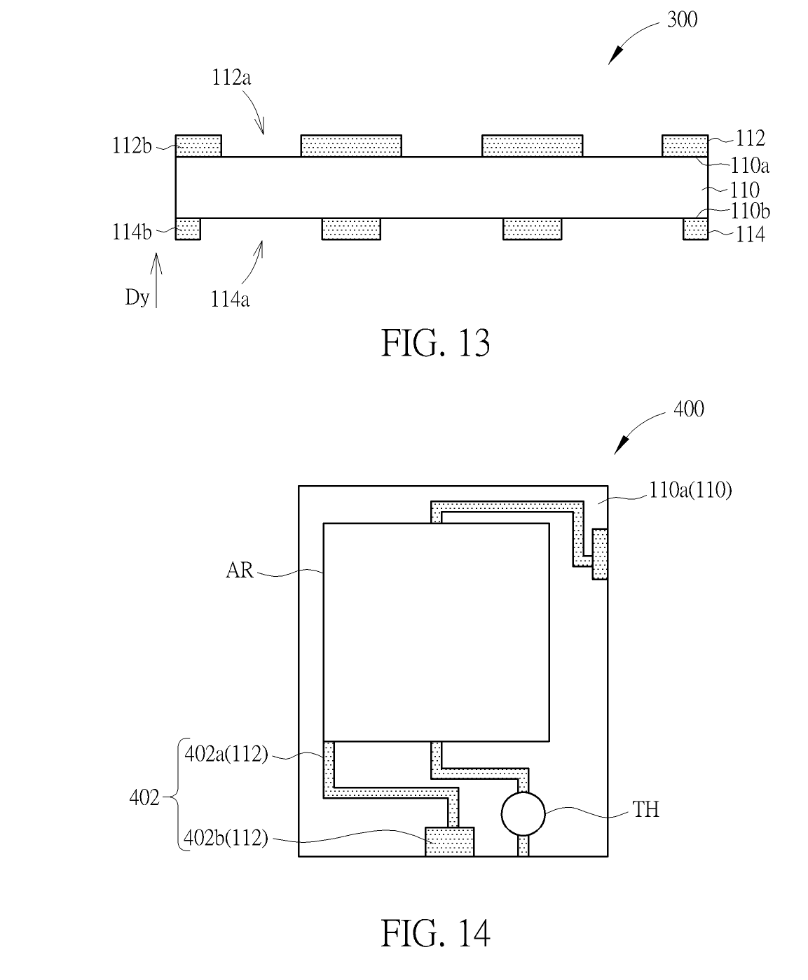

FIG. 13 is a schematic diagram showing a cross-section of a flexible substrate structure of a third embodiment of the present invention, wherein FIG. 13 does not show the through holes TH in order to simplify the schematic diagram. As shown in FIG. 13, compared to the first embodiment, the first patterned metal layer 112 of the flexible substrate structure 300 of this embodiment does not completely overlap the second patterned metal layer 114 along the direction Dy perpendicular to the first surface 110a. In other words, the pattern of the first patterned metal layer 112 is not the same as the pattern of the second patterned metal layer 114. In this embodiment, the second patterned metal layer 114 partially overlaps the first patterned metal layer 112, but is not limited thereto. Moreover, in this embodiment, a width of the first strip structure 112b of the first patterned metal layer 112 is greater than a width of the second strip structure 114b of the second patterned metal layer 114, an area of the first opening 112a is smaller than an area of the second opening 114a, and the first opening 112a is situated in the second opening 114a along the direction Dy perpendicular to the first surface 110a, but the embodiment is not limited thereto. The disposition of the patterned metal layers, the number of openings, the area of the opening and the location of the opening may be designed depending on requirements.

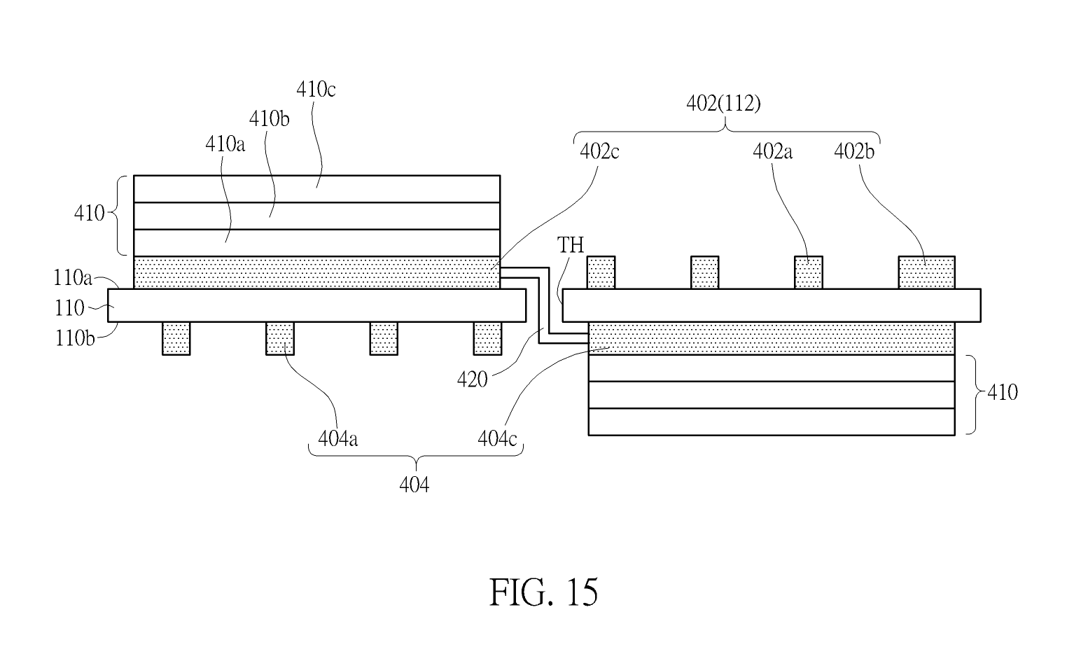

FIG. 14 is a schematic diagram showing a top view of a flexible substrate structure of a fourth embodiment of the present invention, and FIG. 15 is a schematic diagram showing a top view of the flexible substrate structure with an electronic device of the fourth embodiment of the present invention, wherein FIG. 14 only shows the first surface 110a and structures disposed on the first surface 110a. As shown in FIG. 14 and FIG. 15, the flexible substrate structure 400 of this embodiment is configured to be a base on which one or more electronic devices 410 are disposed. Note that FIG. 14 only shows a portion of the flexible substrate structure 400 of this embodiment, and does not show the electronic devices 410 directly. Thus, in this embodiment, the first patterned metal layer 112 and the second patterned metal layer 114 are configured to be electronic components utilized for electrical connection, and the first patterned metal layer 112 and the second patterned metal layer 114 are electrically connected between the electronic devices 410 on the flexible substrate structure 400. In FIG. 15, the electronic devices 410 may be disposed on at least one of the first patterned metal layer 112 and the second patterned metal layer 114, such that the electronic devices 410 may be electrically connected to at least one of the first patterned metal layer 112 and the second patterned metal layer 114. In detail, in this embodiment, the first patterned metal layer 112 includes a plurality of first electronic components 402, and the second patterned metal layer 114 includes a plurality of second electronic components 404, wherein the first electronic components 402 and the second electronic components 404 may include conductive lines 402a and 404a, electrodes 402c and 404c, a bonding pad 402b or a reflecting component for example, but is not limited thereto. The conductive lines 402a and 404a may be utilized for transmitting signals or be circuits having specific functions. Regarding the material, the first patterned metal layer 112 and the second patterned metal layer 114 may include metal having good conductivity, such as silver or copper, but this is not limited thereto. Moreover, in FIG. 14, the flexible substrate structure 400 may have an active region AR situated on at least one of the first surface 110a and the second surface 110b of the flexible substrate 110, and the electronic devices 410 are disposed within the active region AR. Components such as conductive lines, electrodes or bonding pads within the active region AR may be formed of the first electronic components 402 or the second electronic components 404, so as to be electrically connected to the electronic devices 410. Note that FIG. 14 only shows the position of the active region AR, and does not show the first electronic components 402 of the first patterned metal layer 112 within the active region AR. The electronic devices 410 may be devices such as display devices (such as OLEDs), photo-sensing devices, ICs, passive devices (such as capacitors), and active devices (such as thin film transistors). For example, as shown in FIG. 15, the electronic device 410 disposed on the electrode 402c formed of the first patterned metal layer 112 is the photo-sensing device, wherein the electrode 402c may be a bottom electrode, and the photo-sensing device may further include an interlayer dielectric layer 410a, photo-sensing layer 410b and the electrode layer 410c serving as a top electrode, but is not limited thereto.

At least one of the first electronic components 402 of this embodiment is electrically connected to at least one of the second electronic components 404 through the through hole TH. In detail, a conductive bump 420 may be disposed in the through hole TH, and two ends of the conductive bump 420 may be respectively connected to the first electronic component 402 and the second electronic component 404, such that the first electronic component 402 and the second electronic component 404 are electrically connected to each other via the conductive bump 420. In the manufacturing process, after forming the through hole TH, the conductive bump 420 may be formed in the through hole TH by processes such as printing, spraying, evaporation, such that at least one of the first electronic components 402 is electrically connected to at least one of the second electronic components 404 via the conductive bump 420, but the manufacturing method is not limited thereto.

In summary, because the flexible substrate structure of the present invention is formed of the flexible substrate and two patterned metal layers having at least one metal film, the structural stability of the flexible substrate structure configured to be the mask may be increased, thereby reducing adverse conditions such as wrinkles, bending or warping and increasing the yield rate of the electronic product. Furthermore, owing to the advance in structural stability, the distance between the through holes and the number of through holes TH does not need to be decreased therefore; compared to the conventional metal mask, the structures manufactured by the flexible substrate structure of the present invention may have a higher density, which enhances the quality of the electronic product manufactured by the flexible substrate structure. The flexible substrate structure of the present invention may also be configured to be a base on which the electronic device is disposed, in which electronic devices at two sides may be used to manufacture the electronic product. In addition, two patterned metal layers of the flexible substrate structure of the present invention may be formed simultaneously by the electroplating process; thus, the process time and manufacturing cost may be reduced, which enhances the convenience of the manufacturing process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1: A flexible substrate structure, comprising:
a flexible substrate having a first surface and a second surface, wherein the second surface is opposite the first surface;
a first patterned metal layer disposed on the first surface of the flexible substrate; and
a second patterned metal layer disposed on the second surface of the flexible substrate;
wherein the flexible substrate has at least one through hole.

2: The flexible substrate structure of claim 1, wherein the first patterned metal layer completely overlaps the second patterned metal layer along a direction perpendicular to the first surface.

3: The flexible substrate structure of claim 1, wherein the first patterned metal layer does not completely overlap the second patterned metal layer along a direction perpendicular to the first surface.

4: The flexible substrate structure of claim 1, wherein an edge of the through hole does not overlap the first patterned metal layer and the second patterned metal layer along a direction perpendicular to the first surface.

5: The flexible substrate structure of claim 1, wherein the first patterned metal layer has at least one first opening, and the through hole is situated in the first opening.

6: The flexible substrate structure of claim 5, wherein the second patterned metal layer has at least one second opening, and the through hole is situated in the second opening.

7: The flexible substrate structure of claim 5, wherein a distance between an edge of the through hole and an edge of the first opening ranges from 0.5 μm to 500 μm.

8: The flexible substrate structure of claim 1, wherein the first patterned metal layer has a plurality of first openings, and the first openings are arranged in an array.

9: The flexible substrate structure of claim 1, wherein the first patterned metal layer comprises a plurality of strip structures, and a width of the strip structures ranges from 0.5 μm to 1000 μm.

10: The flexible substrate structure of claim 1, wherein an edge of the through hole overlaps the first patterned metal layer and the second patterned metal layer along a direction perpendicular to the first surface.

11: The flexible substrate structure of claim 1, wherein the flexible substrate has a plurality of through holes, and a distance between two adjacent through holes within the plurality of through holes ranges from 0.5 μm to 500 μm.

12: The flexible substrate structure of claim 1, wherein the flexible substrate has a plurality of through holes, and the through holes are arranged in an array.

13: The flexible substrate structure of claim 1, wherein the flexible substrate structure is configured to be a mask.

14: The flexible substrate structure of claim 1, wherein the flexible substrate structure is configured to be a base on which an electronic device is disposed, the electronic device is disposed on at least one of the first patterned metal layer and the second patterned metal layer, the first patterned metal layer has a plurality of first electronic components, and the second patterned metal layer has a plurality of second electronic components.

15: The flexible substrate structure of claim 14, wherein at least one of the first electronic components is electrically connected to at least one of the second electronic components through the through hole.

16: The flexible substrate structure of claim 1, wherein the first patterned metal layer and the second patterned metal layer comprise at least one metal material, the first patterned metal layer and the second patterned metal layer have at least one layer, and the first patterned metal layer and the second patterned metal layer are formed by an electroplating process or an attaching process.

17: A manufacturing method of a flexible substrate structure, comprising:
providing a flexible substrate, the flexible substrate having a first surface and a second surface which is opposite the first surface;
forming a first patterned metal layer on the first surface of the flexible substrate, and forming a second patterned metal layer on the second surface of the flexible substrate; and
performing a through hole process for forming at least one through hole in the flexible substrate.

18: The manufacturing method of the flexible substrate structure of claim 17, wherein an edge of the through hole overlaps the first patterned metal layer and the second patterned metal layer along a direction perpendicular to the first surface.

19: The manufacturing method of the flexible substrate structure of claim 17, wherein the first patterned metal layer has a plurality of first electronic components, and the second patterned metal layer has a plurality of second electronic components.

20: The manufacturing method of the flexible substrate structure of claim 17, wherein a method of forming the first patterned metal layer and the second patterned metal layer comprises an electroplating process or an attaching process.
